(19) United States
(12) Patent Application Publication
(10) Pub. No.: US 2025/0357103 A1
(43) Pub. Date: Nov. 20, 2025

(54) MICROWAVE PLASMA-ENHANCED DEPOSITION OF SILICON OXIDE

(71) Applicant: Applied Materials, Inc., Santa Clara, CA (US)

(72) Inventors: Baorui Cheng, Santa Clara, CA (US); Jialiang Wang, Milpitas, CA (US); Kashish Sharma, Santa Clara, CA (US); Abhijit Basu Mallick, Sunnyvale, CA (US)

(73) Assignee: Applied Materials, Inc., Santa Clara, CA (US)

(21) Appl. No.: 18/667,148

(22) Filed: May 17, 2024

(51) Int. Cl. H01L 21/02; H10B 12/00; H10B 41/35; H10B 43/35

(52) U.S. Cl. CPC H01L 21/02164; H01L 21/02274; H01L 21/0228; H10B 12/01; H10B 41/35; H10B 43/35

(57) ABSTRACT

Methods of depositing silicon oxide (SiOx) films by plasma-enhanced atomic layer deposition (PEALD) are disclosed. The methods includes exposing a semiconductor substrate to a silicon-containing precursor and an oxygen-containing plasma to deposit the silicon oxide (SiOx) films. The oxygen-containing plasma used in the PEALD process is a microwave plasma generated by a microwave plasma source. The silicon oxide (SiOx) films may be used for semiconductor device and/or microelectronic device manufacturing applications.

### TECHNICAL FIELD

Embodiments of the disclosure generally relate to the field of semiconductor device manufacturing. More particularly, embodiments of the disclosure are directed to methods of depositing silicon oxide (SiOx) by plasma-enhanced atomic layer deposition (PEALD) using a microwave plasma generated by a microwave plasma source.

### BACKGROUND

Silicon oxide (SiOx) films have attractive dielectric material properties. These films have been proposed and tested for applications from front-end of line (FEOL) to back-end of line (BEOL) processes and parts of semiconductor devices and microelectronic devices. Generally, FEOL refers to the first portion of integrated circuit fabrication, including transistor fabrication, middle of line (MOL) connects the transistor and interconnect parts of a chip using a series of contact structures, and back-end of line (BEOL) refers to a series of process steps after transistor fabrication through completion of a wafer.

Low temperature, e.g., less than or equal to 600° C., atomic layer deposition (ALD) of silicon oxide (SiOx) films are used in many semiconductor applications. It is thought that many of these low temperature applications are deposited by plasma-enhanced ALD (PEALD) due to poor film quality by low temperature thermal processes, e.g., a thermal ALD process which does not involve the use of plasma.

PEALD film quality varies based on the surface (e.g., a substrate) on which the film is deposited. In particular, it has been found that PEALD film quality varies based on, for example, the material of the substrate and the geometry of the substrate. PEALD may also utilize a single plasma exposure to perform both a silicon-containing precursor-oxygen reaction step to form a film and a film densification step.

Unfortunately, the combination of the reaction step and the densification step leads to the incorporation of reaction by-products into the films as impurities, thereby causing poorer film quality. Further, the plasma species may strip hydrogen from the substrate surface, thereby reducing sites for further precursor adsorption.

Current PEALD approaches, e.g., (1) exposure to silicon-containing precursor, purge, exposure to thermal oxygen-containing gas, purge, and/or (2) exposure to silicon-containing precursor, purge, exposure to plasma of an oxygen-containing gas, and purge, may independently produce films of poor quality for advancing semiconductor device manufacturing requirements.

As memory device and logic device structures get more complicated with deeper trenches/holes and narrower critical dimensions (CD), conventional plasma-enhanced chemical vapor deposition (PECVD) and PEALD using an RF plasma source, a remote plasma source, an inductively coupled plasma (ICP) source, or a capacitively coupled plasma (CCP) source, for example, often fail to conformally deposit the film on memory device and logic device structures due to limited radical density and ion-bombardment damage.

Accordingly, there is a need for methods of depositing silicon oxide (SiOx) films that provide improved film quality and improved film conformality to meet advancing semiconductor device manufacturing requirements.

### SUMMARY

One or more embodiments of the disclosure are directed to a method comprising: exposing a semiconductor substrate to a silicon-containing precursor and an oxygen-containing plasma to deposit a silicon oxide (SiOx) film, wherein the oxygen-containing plasma is a microwave plasma generated by a microwave plasma source.

Additional embodiments of the disclosure are directed to a method of manufacturing a semiconductor device. The method comprises exposing a semiconductor substrate to a silicon-containing precursor and an oxygen-containing plasma to deposit a silicon oxide (SiOx) film wherein the oxygen-containing plasma comprises one or more of oxygen (O₂), ozone (O₃), or nitrous oxide (N₂O), the oxygen-containing plasma is a microwave plasma generated by a microwave plasma source, and the method is performed at a temperature in a range of from 100° C. to 700° C.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended Drawings. It is to be noted, however, that the appended Drawings illustrate only typical embodiments of the present disclosure and are therefore not to be considered limiting of its scope, for the disclosure may admit to other equally effective embodiments.

FIG. 1A illustrates a process flow diagram of a method in accordance with one or more embodiments of the present disclosure;

FIG. 1B illustrates a process flow diagram of a method in accordance with one or more embodiments of the present disclosure;

FIG. 2A illustrates a cross-sectional schematic view of a semiconductor substrate having a silicon oxide (SiOx) film deposited thereon in accordance with one or more embodiments of the present disclosure;

FIG. 2B illustrates a cross-sectional schematic view of a semiconductor substrate having a feature formed therein in accordance with one or more embodiments of the present disclosure;

FIG. 2C illustrates deposition of a silicon oxide (SiOx) film on the semiconductor substrate of FIG. 2B in accordance with one or more embodiments of the present disclosure;

FIG. 3 illustrates a schematic representation of a processing tool comprising a modular high-frequency emission source with a plasma showerhead assembly that comprises a plurality of applicators in accordance with one or more embodiments of the present disclosure;

FIG. 4 illustrates a block diagram of a high-frequency emission module in accordance with one or more embodiments of the present disclosure;

FIG. 5 illustrates a schematic exploded perspective view of the plasma showerhead assembly of FIG. 3 in accordance with one or more embodiments of the present disclosure; and

FIG. 6 illustrates a cross-sectional view of a processing tool in accordance with one or more embodiments of the present disclosure.

To facilitate understanding, identical reference numerals have been used, where possible, to designate identical elements that are common to the Figures. It is contemplated that elements and features of one embodiment may be beneficially incorporated in other embodiments without further recitation.

### DETAILED DESCRIPTION

Before describing embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of “about.”

Spatially relative terms, such as “beneath,” “below,” “lower,” “above,” “upper” and the like, may be used herein for ease of description to describe one element or feature's relationship to another element(s) or feature(s) as illustrated in the Figures. It will be understood that the spatially relative terms are intended to encompass different orientations of a device in use or operation in addition to the orientation depicted in the Figures. For example, if the device in the Figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiments,” or “an embodiment” means that a particular feature, structure, material, or characteristic described in connection with the embodiment is included in at least one embodiment of the disclosure. Thus, the appearances of the phrases such as “in one embodiment,” “in some embodiments,” “in certain embodiments,” “in one or more embodiments,” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” or “wafer” refers to a surface, or portion of a surface, upon which a process acts. It will also be understood by those skilled in the art that reference to a substrate can refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. Substrates include, without limitation, semiconductor substrates. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

“Atomic layer deposition” or “cyclical deposition” as used herein refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially.

As used herein, the terms “purge” or “purging” each independently include any suitable purge process that removes unreacted precursor/reactant, reaction products, and by-products from the process region (e.g., a processing chamber). The suitable purge process includes moving the substrate through a gas curtain to a portion or sector of the processing region that contains none or substantially none of the precursor/reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the processing chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the terms “thermal” or “thermal process(es)” each independently refer to a deposition technique that does not involve the use of plasma. As used herein, the term “plasma” refers to a composition have ionically charged species and uncharged neutral and radical species.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

One or more layers deposited on the substrate or substrate surface by atomic layer deposition (ALD) or plasma-enhanced ALD (PEALD) are conformal. As used herein, as will be understood by the skilled artisan, a layer/film which is “conformal” or “conformally deposited” refers to a layer/film where the thickness is about the same throughout. A layer/film which is conformal varies in thickness by less than or equal to about 5%, 2%, 1% or 0.5%.

Plasma-enhanced ALD (PEALD) methods add a plasma exposure to traditional ALD methods. In some PEALD methods, an oxygen source is provided as the plasma. The primary benefit of PEALD methods is the relatively low substrate temperature, e.g., less than or equal to 600° C., during processing.

The methods described herein include processing a semiconductor substrate in a processing chamber. As used herein, the specific region in which the semiconductor substrate is processed (i.e., where the methods are performed) can be referred to as a “processing region” within the processing chamber. It will be understood and appreciated by the skilled artisan that processing the semiconductor substrate in the processing chamber is inclusive of processing the semiconductor substrate in the processing region, without specifically referring to the processing region in each instance.

Embodiments of the present disclosure are directed to provide methods of depositing silicon oxide (SiOx) films as part of a semiconductor device manufacturing process and/or a microelectronic device manufacturing process, e.g., for semiconductor device and microelectronic device applications. Some embodiments advantageously provide methods of depositing silicon oxide (SiOx) films for FEOL and BEOL processes and parts.

Some embodiments are directed to methods of depositing silicon oxide (SiOx) films by plasma-enhanced ALD (PEALD). Some embodiments are directed to methods of depositing silicon oxide (SiOx) films by plasma-enhanced atomic layer deposition (PEALD) using a microwave plasma generated by a microwave plasma source.

Some embodiments provide silicon oxide (SiOx) films deposited on a substrate comprising a feature, such as, for example, at least one vertically extending feature and/or at least one laterally extending feature.

The skilled artisan will recognize that the use of a molecular formula such as silicon oxide (SiOx) does not imply specific stoichiometric relation between the elements but merely the identity of the major components of the film, i.e., silicon and oxygen. In some embodiments, the major composition of the specified film (i.e., the sum of the atomic percent of the specified atoms) is greater than or equal to about 95%, 98%, 99%, 99.5%, or 99.9% of the film, on an atomic basis. In some embodiments, the silicon oxide (SiOx) film comprises SiO₂.

Some embodiments advantageously provide silicon oxide (SiOx) films having improved film quality. There are multiple metrics used to measure silicon oxide (SiOx) film quality. One of the most common metrics used to measure silicon oxide (SiOx) film quality is the wet etch rate (WER) of the deposited film under dilute hydrofluoric (HF) acid etch solution, such as dilute HF 100:1. The wet etch rate (WER) can be measured in, for example, nanometers per minute (nm/min). Some embodiments advantageously provide a silicon oxide (SiOx) film that has a reduced etch amount in Angstroms (Å) using dilute HF 100:1, which represents an improved wet etch rate (WER), compared to current PEALD approaches.

Some embodiments advantageously provide silicon oxide (SiOx) films that have about the same wet etch rate (WER) in different regions of a semiconductor substrate having a feature, e.g., a trench, having a top surface, two sidewalls comprising a dielectric material, and a bottom comprising a metallic material extending into the semiconductor substrate. In specific embodiments, the silicon oxide (SiOx) films advantageously have about the same wet etch rate (WER) on the top surface and along the two sidewalls and bottom.

As memory device and logic device structures get more complicated with deeper trenches/holes and narrower critical dimensions (CD), conventional plasma-enhanced chemical vapor deposition (PECVD) and PEALD using an RF plasma source, a remote plasma source, an inductively coupled plasma (ICP) source, or a capacitively coupled plasma (CCP) source, for example, often fail to conformally deposit the film on memory device and logic device structures due to limited radical density and ion-bombardment damage.

Embodiments of the disclosure advantageously provide methods of depositing silicon oxide (SiOx) films having improved film conformality compared to current and conventional PECVD/PEALD processes. Advantageously, some embodiments directed to methods of depositing silicon oxide (SiOx) films by plasma-enhanced atomic layer deposition (PEALD) using a microwave plasma generated by a microwave plasma source provide high radical density and low ion energy, therefore allowing conformal and high quality film deposition in memory device and logic device structures. Embodiments of the disclosure using a microwave plasma generated by a microwave plasma source advantageously achieve saturation of plasma treatment in a shorter time period compared to conventional plasma-enhanced chemical vapor deposition (PECVD) and PEALD using an RF plasma source, a remote plasma source, an inductively coupled plasma (ICP) source, or a capacitively coupled plasma (CCP) source, for example. Embodiments of the disclosure using a microwave plasma generated by a microwave plasma source advantageously avoid ion-bombardment damage compared to conventional plasma-enhanced chemical vapor deposition (PECVD) and PEALD using an RF plasma source, a remote plasma source, an inductively coupled plasma (ICP) source, or a capacitively coupled plasma (CCP) source, for example.

Some embodiments advantageously provide methods of depositing silicon oxide (SiOx) films having improved film quality and improved conformality on a substrate comprising at least one vertically extending feature, e.g., conformally on the at least one vertically extending feature. Some embodiments provide methods of depositing silicon oxide (SiOx) films having improved film quality and improved conformality on a substrate comprising at least one laterally extending feature, e.g., conformally on the at least one laterally extending feature.

Some embodiments advantageously provide the ability to control the thickness of silicon oxide (SiOx) films to Angstrom-level accuracy in accordance with the methods described herein.

One or more embodiments are directed to methods of depositing silicon oxide (SiOx) in high aspect ratio structures, e.g., in memory devices or logic devices, including, but not limited to, 3D-NAND, dynamic random-access memory (DRAM) cells, 3D DRAM, Fin field effect transistors (FinFET), gate-all-around (GAA) transistors, and the like. As used herein, a “high aspect ratio” structure has an aspect ratio greater than or equal to about 20:1, such as, for example, in a range of from 50:1 to 150:1. In some embodiments, the silicon oxide (SiOx) film is conformally deposited on the high aspect ratio feature, such as at least one vertically extending feature and/or at least one laterally extending feature.

Additional embodiments of the disclosure provide a plasma showerhead assembly, e.g., an assembly, for a processing tool. In one or more embodiments, the assembly comprises a conductive plate and a dielectric faceplate.

In one or more embodiments, the conductive plate includes a first surface and a second surface opposite to the first surface defining a conductive plate thickness, a plurality of resonator openings extending from the first surface through the conductive plate to the second surface of the conductive plate, gas channels within the conductive plate thickness, a plurality of conductive plate gas openings on the second surface of the conductive plate in fluid communication with the gas channels within the conductive plate thickness.

In one or more embodiments, the dielectric faceplate comprises a first surface and a second surface opposite to the first surface defining a dielectric faceplate thickness, a plurality of dielectric resonators protruding from the first surface and configured so that the resonators fit into the plurality of the resonator openings of the conductive plate when assembled, each resonator having a geometric center; and a plurality of dielectric faceplate gas openings extending through the dielectric faceplate thickness.

In one or more embodiments, the assembly comprises a plurality of o-rings surrounding the conductive plate gas openings and the dielectric faceplate gas openings, wherein the dielectric faceplate gas openings are in fluid communication with the conductive plate gas openings and the o-rings are configured to seal the dielectric faceplate gas openings and the conductive plate gas openings from atmospheric pressure.

The assembly described herein is a microwave plasma source that may be used to generate a microwave plasma of any of the plasma compositions described herein. Advantageously, the energy of ions in a microwave plasma can be tuned low enough that it does not substantially damage dielectric materials. Further, the disclosed methods are self-limiting by only affecting the silicon oxide (SiOx) films deposited and not the other layers, such as a dielectric layer, in the structures.

The embodiments of the disclosure are described by way of the Figures, which illustrate processes, substrates, and apparatuses in accordance with one or more embodiments of the disclosure. The processes and resulting substrates shown are merely illustrative of the disclosed methods, and the skilled artisan will recognize that the disclosed methods are not limited to the illustrated applications.

In the following description, numerous specific details are set forth in order to provide a thorough understanding of the embodiments of the disclosure. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

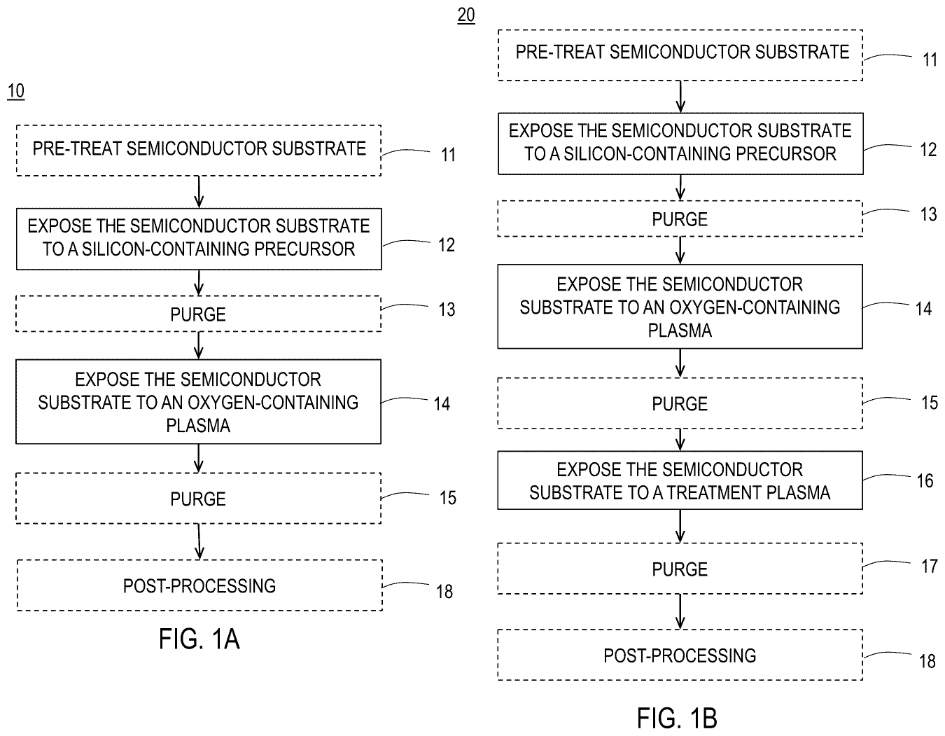

FIG. 1A illustrates a process flow diagram of a method 10 and FIG. 1B illustrates a process flow diagram of a method 20. The methods, e.g., method 10 and method 20, may be performed at any suitable processing conditions, and the processing conditions may vary depending upon the application for which the semiconductor substrate 50 and the silicon oxide (SiOx) film 54 deposited thereon are used. In one or more embodiments, each of the methods, e.g., method 10 and method 20 independently comprise a plasma-enhanced atomic layer deposition (PEALD) process.

In one or more embodiments, each of the methods, e.g., method 10 and method 20, are independently performed at a temperature in a range of from 100° C. to 700° C. In one or more embodiments of FIG. 1A and FIG. 1B, the dashed lines are used to denote that the stated operation is optional.

Referring to FIG. 1A, the method 10 begins by optionally pre-treating the semiconductor substrate 50 at operation 11. The pre-treatment can be any suitable pre-treatment known to the skilled artisan. Suitable pre-treatments include, but are not limited to, pre-heating, cleaning, soaking, or native oxide removal, as examples. In FIG. 1B, the method 20 begins by optionally pre-treating the semiconductor substrate 50 at operation 11.

Referring to FIGS. 1A and 1B, each of the method 10 and the method 20 include exposing the semiconductor substrate 50 to a silicon-containing precursor at operation 12.

The silicon-containing precursor may be any suitable precursor that includes silicon. In some embodiments, the silicon-containing precursor includes one or more of a silane, an aminosilane, an organosilane, or a halosilane. In some embodiments, the silicon-containing precursor includes one or more of silane (SiH₄), disilane (Si₂H₆), diisopropylamino silane (DIPAS), bis(diethylamino) silane (BDEAS), tris(dimethylamino) disilane (TADS), tris(dimethylamino) silane (TDMAS), di(sec-butylamino) silane (DSBAS), bis(tertiarybutylamino) silane (BTBAS), methylsilane, ethylsilane, tetraethyl orthosilicate (TEOS), chlorosilane (HsSiCl), dichlorosilane (H₂SiCl₂), chloromethylsilane, trichlorosilane (HSiCl₃), tetrachlorosilane (SiCl₄), iodosilane (H₃ISi), diiodosilane (H₂I₂Si), triiodosilane (HI₃Si), or tetraiodosilane (I₄Si). In some embodiments, the silicon-containing precursor is bis(diethylamino) silane (BDEAS).

In some embodiments, the silicon-containing precursor further comprises a non-reactive species, such as, for example, an inert gas. In one or more embodiments, the silicon-containing precursor further comprises one or more of nitrogen (N₂), argon (Ar), or helium (He). In one or more embodiments, the silicon-containing precursor further comprises nitrogen (N₂). In one or more embodiments, the silicon-containing precursor further consists essentially of nitrogen (N₂). In one or more embodiments, the silicon-containing precursor further consists of nitrogen (N₂). In one or more embodiments, the silicon-containing precursor further comprises argon (Ar). In one or more embodiments, the silicon-containing precursor further consists essentially of argon (Ar). In one or more embodiments, the silicon-containing precursor further consists of argon (Ar). In one or more embodiments, the silicon-containing precursor further comprises helium (He). In one or more embodiments, the silicon-containing precursor further consists essentially of helium (He). In one or more embodiments, the silicon-containing precursor further consists of helium (He).

Each of the method 10 and the method 20 include exposing the semiconductor substrate 50 to the silicon-containing precursor for a time period in a range of from 0.1 seconds to 60 seconds. In some embodiments, each of the method 10 and the method 20 include exposing the semiconductor substrate 50 to the silicon-containing precursor for 1 second.

Each of the method 10 and the method 20 include exposing the semiconductor substrate 50 to the silicon-containing precursor at a dose pressure in a range of from 0.1 Torr to 20 Torr. In some embodiments, each of the method 10 and the method 20 include exposing the semiconductor substrate 50 to the silicon-containing precursor at a dose pressure of 4 Torr.

Each of the method 10 and the method 20 include exposing the semiconductor substrate 50 to the silicon-containing precursor at a flow rate in a range of from 0 standard cubic centimeters per minute (sccm) to 5000 sccm. In some embodiments, each of the method 10 and the method 20 include exposing the semiconductor substrate 50 to the silicon-containing precursor at a flow rate of 500 sccm.

In one or more embodiments, the silicon-containing precursor is diluted with a non-reactive species, such as, for example, an inert gas, during operation 12. In one or more embodiments, the silicon-containing precursor is diluted with argon (Ar) at a flow rate in a range of from 0 sccm to 5000 sccm during the method 10 and/or the method 20. In one or more embodiments, the silicon-containing precursor is diluted with argon (Ar) at a flow rate of 2000 sccm during the method 10 and/or the method 20.

In one or more embodiments, exposing the semiconductor substrate 50 to the silicon-containing precursor at operation 12 includes a “pump step” and a “purge step”.

Generally, as used herein with respect to operation 12, the pump step has no active gas supply (i.e., the silicon-containing precursor is not delivered to the processing region) in order to drive the processing region to the highest vacuum level and remove any unreacted silicon-containing precursor, reaction products, and by-products during the purge step (optional operation 13).

The duration of the pump step is in a range of from 0 seconds to 120 seconds. In some embodiments, the duration of the pump step is 30 seconds. In some embodiments, each of the method 10 and the method 20 include purging the semiconductor substrate 50 at optional operation 13 for a time period in a range of from 0 seconds to 120 seconds. In some embodiments, each of the method 10 and the method 20 include purging the semiconductor substrate 50 at optional operation 13 for 60 seconds.

Each of the method 10 and the method 20 include exposing the semiconductor substrate 50 to an oxygen-containing plasma at operation 14.

In one or more embodiments, a microwave plasma source is used to generate any of the disclosed plasmas and/or plasma mixtures and may be implemented for the disclosed methods.

One or more embodiments of the present disclosure include modular microwave plasma processing tools. Modular microwave plasma sources advantageously have a high plasma density and very low plasma potential (e.g., less than or equal to 10 eV).

In one or more embodiments, the oxygen-containing plasma is a microwave plasma generated by a microwave plasma source, such as, for example, a modular microwave plasma source as described herein.

The oxygen-containing plasma may be any suitable reactant that includes a plasma generated from oxygen. In some embodiments, the oxygen-containing plasma comprises one or more of oxygen (O₂), ozone (O₃), or nitrous oxide (N₂O). In some embodiments, the oxygen-containing plasma comprises one or more of oxygen (O₂), ozone (O₃), or nitrous oxide (N₂O), and a non-reactive species, such as, for example, an inert gas.

In some embodiments, the oxygen-containing plasma comprises, consists essentially of, or consists of oxygen (O₂).

In some embodiments, the oxygen-containing plasma comprises oxygen (O₂) and nitrogen (N₂). In some embodiments, the oxygen-containing plasma consists essentially of oxygen (O₂) and nitrogen (N₂). In some embodiments, the oxygen-containing plasma consists of oxygen (O₂) and nitrogen (N₂).

In some embodiments, the oxygen-containing plasma comprises oxygen (O₂) and argon (Ar). In some embodiments, the oxygen-containing plasma consists essentially of oxygen (O₂) and argon (Ar). In some embodiments, the oxygen-containing plasma consists of oxygen (O₂) and argon (Ar).

In some embodiments, the oxygen-containing plasma comprises oxygen (O₂) and helium (He). In some embodiments, the oxygen-containing plasma consists essentially of oxygen (O₂) and helium (He). In some embodiments, the oxygen-containing plasma consists of oxygen (O₂) and helium (He).

In some embodiments, the oxygen-containing plasma comprises, consists essentially of, or consists of ozone (O₃).

In some embodiments, the oxygen-containing plasma comprises ozone (O₃) and nitrogen (N₂). In some embodiments, the oxygen-containing plasma consists essentially of ozone (O₃) and nitrogen (N₂). In some embodiments, the oxygen-containing plasma consists of ozone (O₃) and nitrogen (N₂).

In some embodiments, the oxygen-containing plasma comprises ozone (O₃) and argon (Ar). In some embodiments, the oxygen-containing plasma consists essentially of ozone (O₃) and argon (Ar). In some embodiments, the oxygen-containing plasma consists of ozone (O₃) and argon (Ar).

In some embodiments, the oxygen-containing plasma comprises ozone (O₃) and helium (He). In some embodiments, the oxygen-containing plasma consists essentially of ozone (O₃) and helium (He). In some embodiments, the oxygen-containing plasma consists of ozone (O₃) and helium (He).

In some embodiments, the oxygen-containing plasma comprises, consists essentially of, or consists of nitrous oxide (N₂O).

In some embodiments, the oxygen-containing plasma comprises nitrous oxide (N₂O) and nitrogen (N₂). In some embodiments, the oxygen-containing plasma consists essentially of nitrous oxide (N₂O) and nitrogen (N₂). In some embodiments, the oxygen-containing plasma consists of nitrous oxide (N₂O) and nitrogen (N₂).

In some embodiments, the oxygen-containing plasma comprises nitrous oxide (N₂O) and argon (Ar). In some embodiments, the oxygen-containing plasma consists essentially of nitrous oxide (N₂O) and argon (Ar). In some embodiments, the oxygen-containing plasma consists of nitrous oxide (N₂O) and argon (Ar).

In some embodiments, the oxygen-containing plasma comprises nitrous oxide (N₂O) and helium (He). In some embodiments, the oxygen-containing plasma consists essentially of nitrous oxide (N₂O) and helium (He). In some embodiments, the oxygen-containing plasma consists of nitrous oxide (N₂O) and helium (He).

Each of the method 10 and the method 20 include exposing the semiconductor substrate 50 to the oxygen-containing plasma for a time period in a range of from 0.1 seconds to 120 seconds. In some embodiments, each of the method 10 and the method 20 include exposing the semiconductor substrate 50 to the oxygen-containing plasma for 60 seconds.

Each of the method 10 and the method 20 include exposing the semiconductor substrate 50 to the oxygen-containing plasma at a plasma power in a range of from 0 Watts (W) to 200 Watts (W). In some embodiments, each of the method 10 and the method 20 include exposing the semiconductor substrate 50 to the oxygen-containing plasma at a plasma power of 195 Watts (W).

Each of the method 10 and the method 20 include exposing the semiconductor substrate 50 to the oxygen-containing plasma at a plasma pressure in a range of from 0.1 Torr to 20 Torr. In some embodiments, each of the method 10 and the method 20 include exposing the semiconductor substrate 50 to the oxygen-containing plasma at a plasma pressure of 6 Torr.

Each of the method 10 and the method 20 include exposing the semiconductor substrate 50 to the oxygen-containing plasma at a flow rate in a range of from 0 sccm to 5000 sccm. In some embodiments, each of the method 10 and the method 20 include exposing the semiconductor substrate 50 to the oxygen-containing plasma at a flow rate of 200 sccm.

In one or more embodiments, the oxygen-containing plasma is diluted with a non-reactive species, such as, for example, an inert gas, during operation 14. In one or more embodiments, the oxygen-containing plasma is diluted with argon (Ar) at a flow rate in a range of from 0 sccm to 5000 sccm during the method 10 and/or the method 20. In one or more embodiments, the oxygen-containing plasma is diluted with argon (Ar) at a flow rate of 2000 sccm during the method 10 and/or the method 20.

In one or more embodiments, exposing the semiconductor substrate 50 to the oxygen-containing plasma at operation 14 includes a “pump step” and a “purge step”.

Generally, as used herein with respect to operation 14, the pump step has no active plasma supply (i.e., the oxygen-containing plasma is not delivered to the processing region) in order to drive the processing region to the highest vacuum level and remove any unreacted oxygen-containing plasma, reaction products, and by-products during the purge step (optional operation 15).

The duration of the pump step is in a range of from 0 seconds to 120 seconds. In some embodiments, the duration of the pump step is 60 seconds. In some embodiments, each of the method 10 and the method 20 include purging the semiconductor substrate 50 at optional operation 15 for a time period in a range of from 0 seconds to 120 seconds. In some embodiments, each of the method 10 and the method 20 include purging the semiconductor substrate 50 at optional operation 15 for 60 seconds.

The method 10 includes an optional post-processing operation 18 after optionally purging the semiconductor substrate 50 at operation 15. The optional post-processing operation 18 will be described in further detail herein.

Referring to FIG. 1B, the method 20 includes exposing the semiconductor substrate 50 to a treatment plasma at operation 16.

The treatment plasma can have the same composition as the oxygen-containing plasma disclosed herein. In one or more embodiments, the treatment plasma has the same composition as the oxygen-containing plasma disclosed herein. In some embodiments, the treatment plasma comprises, consists essentially of, or consists of a mixture of oxygen (O₂) and nitrogen (N₂). In some embodiments, the treatment plasma comprises, consists essentially of, or consists of a mixture of oxygen (O₂) and argon (Ar). In some embodiments, the treatment plasma comprises, consists essentially of, or consists of a mixture of oxygen (O₂) and helium (He).

The method 20 includes exposing the semiconductor substrate 50 to the treatment plasma for a time period in a range of from 0.1 seconds to 120 seconds. In some embodiments, the method 20 includes exposing the semiconductor substrate 50 to the treatment plasma for 60 seconds.

The method 20 includes exposing the semiconductor substrate 50 to the treatment plasma at a plasma power in a range of from 0 Watts (W) to 200 Watts (W). In some embodiments, the method 20 includes exposing the semiconductor substrate 50 to the treatment plasma at a plasma power of 195 Watts (W).

The method 20 includes exposing the semiconductor substrate 50 to the treatment plasma at a plasma pressure in a range of from 0.1 Torr to 20 Torr. In some embodiments, the method 20 includes exposing the semiconductor substrate 50 to the treatment plasma at a plasma pressure of 1 Torr.

The method 20 include exposing the semiconductor substrate 50 to the treatment plasma at a flow rate in a range of from 0 sccm to 5000 sccm. In specific embodiments, where the treatment plasma comprises, consists essentially of, or consists of a mixture of oxygen (O₂) and helium (He), the oxygen (O₂) and helium (He) are each independently flowed at a flow rate in the range of from 0 sccm to 5000 sccm. In specific embodiments, where the treatment plasma comprises, consists essentially of, or consists of a mixture of oxygen (O₂) and helium (He), the oxygen (O₂) is flowed at a flow rate of 6 sccm and the helium (He) is flowed at a flow rate of 3000 sccm.

In one or more embodiments, exposing the semiconductor substrate 50 to the treatment plasma at operation 16 includes a “pump step” and a “purge step”.

Generally, as used herein with respect to operation 16, the pump step has no active plasma supply (i.e., the treatment plasma is not delivered to the processing region) in order to drive the processing region to the highest vacuum level and remove any unreacted treatment plasma, reaction products, and by-products during the purge step (optional operation 17).

The duration of the pump step is in a range of from 0 seconds to 120 seconds. In some embodiments, the duration of the pump step is 60 seconds. In some embodiments, the method 20 includes purging the semiconductor substrate 50 at optional operation 17 for a time period in a range of from 0 seconds to 120 seconds. In some embodiments, the method 20 includes purging the semiconductor substrate 50 at optional operation 17 for 60 seconds.

It will be appreciated that the “pump step” and “purge step” can be collectively described as the pump step having no active gas supply (i.e., the silicon-containing precursor is not delivered to the processing region) and no active plasma supply (i.e., the oxygen-containing plasma and the treatment plasma are not delivered to the processing region) in order to drive the processing region to the highest vacuum level and remove any unreacted silicon-containing precursor, oxygen-containing plasma, treatment plasma, reaction products, and by-products during the purge step (e.g., optional operation 13, operation 15, and/or operation 17).

The method 20 includes an optional post-processing operation 18 after optionally purging the semiconductor substrate 50 at operation 17.

The optional post-processing operation 18 can be any suitable process known to the skilled artisan. If the predetermined thickness has not been met or the predetermined number of cycles (where a “cycle” is one iteration of the operations of the method 10 and/or the method 20) have not been performed, the method 10 and/or the method 20 returns to the first step of the respective method. One or more embodiments of the method 10 and/or the method 20 comprise repeating one or more operations of the respective method to deposit the silicon oxide (SiOx) film 54 to a predetermined thickness and/or until a predetermined number of cycles have been performed.

In one or more embodiments, the method 10 comprises operation 11, operation 12, operation 13, operation 14, operation 15, and operation 18. In one or more embodiments, the method 10 consists essentially of operation 11, operation 12, operation 13, operation 14, operation 15, and operation 18. In one or more embodiments, the method 10 consists of operation 11, operation 12, operation 13, operation 14, operation 15, and operation 18.

In one or more embodiments, the method 20 comprises operation 11, operation 12, operation 13, operation 14, operation 15, operation 16, operation 17, and operation 18. In one or more embodiments, the method 20 consists essentially of operation 11, operation 12, operation 13, operation 14, operation 15, operation 16, operation 17, and operation 18. In one or more embodiments, the method 20 consists of operation 11, operation 12, operation 13, operation 14, operation 15, operation 16, operation 17, and operation 18.

In one or more embodiments, the methods described herein (method 10 and method 20), may be used as part of a semiconductor device manufacturing and/or a microelectronic device manufacturing process. It will be appreciated by the skilled artisan that one or more subsequent operations (e.g., after the method 10 and/or the method 20) can be performed to complete a semiconductor device manufacturing process and/or microelectronic device manufacturing process without undue experimentation.

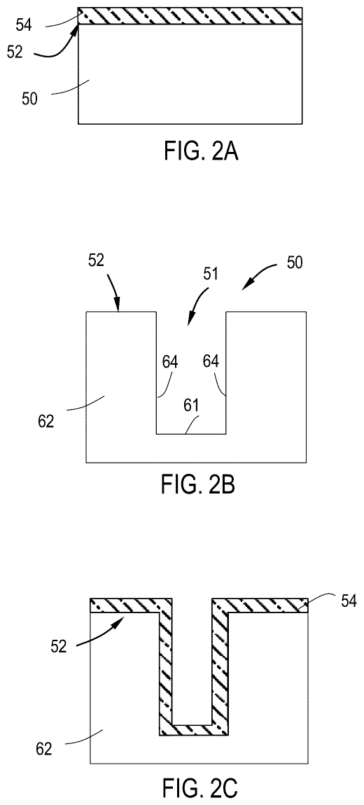

FIG. 2A-2C illustrate cross-sectional schematic views of the semiconductor substrate 50. The semiconductor substrate 50 can be any suitable substrate material. In one or more embodiments, the semiconductor substrate 50 comprises a semiconductor material, e.g., one or more of silicon (Si), germanium (Ge), silicon germanium (SiGe), and/or a metal material, e.g., one or more of tungsten (W), nickel (Ni), cobalt (Co), or titanium (Ti). In one or more embodiments, the semiconductor substrate 50 comprises one or more of silicon (Si) or silicon oxide (SiOx).

The silicon oxide (SiOx) film 54 can be deposited at any suitable processing conditions. The processing conditions may vary based upon the particular application in which the silicon oxide (SiOx) film 54 is used. The silicon oxide (SiOx) film 54 may have any suitable thickness. In one or more embodiments, the silicon oxide (SiOx) film 54 has a thickness in a range of from 20 Angstroms to 1000 Angstroms. The thickness of the silicon oxide (SiOx) film 54 may vary within the range of from 20 Angstroms to 1000 Angstroms based upon the particular application in which the silicon oxide (SiOx) film 54 is used.

Further aspects of the disclosure pertain to a method that is part of a gap fill process. The disclosed methods may be utilized with any device nodes, but may be particularly advantageous in device nodes of about 25 nm or less, for example about 5 nm to about 25 nm. It will be appreciated by the skilled artisan that, in embodiments where the method 10 and/or the method 20 is part of a gap-fill process, the method 10 and/or the method 20 can include one or more subsequent operations, such as, for example, filling the gap with a conductive material to form an interconnect, and that the one or more subsequent operations can be performed without undue experimentation.

FIGS. 2B-2C illustrate cross-sectional schematic views of a semiconductor substrate 50 having a feature, e.g., a trench 51, having a top surface 52, two sidewalls 64 comprising, for example, a dielectric material, and a bottom 61 comprising, for example, a metallic material extending into the semiconductor substrate 50. In one or more embodiments, the trench 51 is a “high aspect ratio” structures, e.g., in memory devices or logic devices, including, but not limited to, 3D-NAND, DRAM, 3D DRAM, FinFET, GAA, and the like.

In FIG. 2C, the silicon oxide (SiOx) film 54 is deposited directly on a top surface 52 of the semiconductor substrate 50, along the two sidewalls 64, and the bottom 61, in accordance with the method 10 and/or the method 20. In one or more embodiments, the silicon oxide (SiOx) film 54 is conformally deposited directly on a top surface 52 of the semiconductor substrate 50, along the two sidewalls 64, and the bottom 61, in accordance with the method 10 and/or the method 20.

Embodiments of the disclosure advantageously provide silicon oxide (SiOx) films having improved film quality. Some advantageously provide a silicon oxide (SiOx) film that has a reduced etch amount in Angstroms (Å) using dilute HF 100:1, which represents an improved wet etch rate (WER), compared to current PEALD approaches.

The silicon oxide (SiOx) films advantageously have about the same wet etch rate (WER) outside the trench 51 (e.g., on the top surface 52) and in the trench 51 (e.g., along the two sidewalls 64 and the bottom 61).

The silicon oxide (SiOx) film 54 formed by the methods described herein (e.g., method 10 and/or method 20) advantageously has a wet etch rate (WER) of less than or equal to 6 nm/min outside the trench 51 (e.g., on the top surface 52). The silicon oxide (SiOx) film 54 formed by the methods described herein (e.g., method 10 and/or method 20) advantageously has a wet etch rate (WER) of less than or equal to 6 nm/min in the trench 51 (e.g., along the two sidewalls 64 and the bottom 61).

The methods described herein may be performed in any suitable processing chamber or processing system such as, for example, the processing tools described herein. The methods described herein may be performed in, for example, a PEALD processing chamber.

Additional embodiments of the disclosure are directed to processing tools. In some embodiments, the processing tool comprises: a central transfer station comprising a robot configured to move a semiconductor substrate (e.g., the semiconductor substrate 50), a plurality of process stations, and a controller connected to the central transfer station and the plurality of process stations. In some embodiments, each process station is connected to the central transfer station and provides a processing region separated from processing regions of adjacent process stations. In some embodiments, the plurality of process stations comprises an atomic layer deposition (ALD) chamber. In some embodiments, the plurality of process stations comprises a plasma-enhanced atomic layer deposition (PEALD) chamber. In some embodiments, the controller is configured to activate the robot to move the semiconductor substrate (e.g., the semiconductor substrate 50) between process stations, and to control a method, such as the method 10 and/or the method 20.

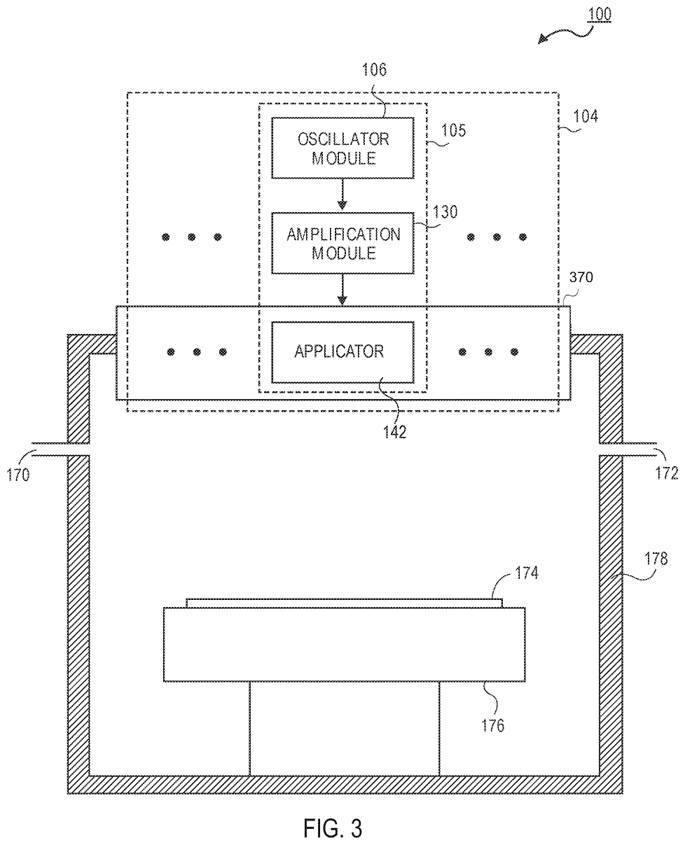

In accordance with one or more embodiments, FIG. 3 illustrates a schematic representation of a processing tool 100. In some embodiments, the processing tool 100 may be a processing tool suitable for any type of processing operation that utilizes a plasma. For example, the processing tool 100 may be a processing tool used for plasma enhanced chemical vapor deposition (PECVD), plasma-enhanced atomic layer deposition (PEALD), etch and selective removal processes, and plasma cleaning. One or more of the operations of the method 10 and/or the method 20 can be performed in the processing tool 100.

The processing tool 100 includes a semiconductor processing chamber 178. In one or more embodiments, the semiconductor processing chamber 178 is a vacuum chamber. In one or more unillustrated embodiments, the vacuum chamber may include a pump for removing gases from the chamber to provide the desired vacuum. Additional embodiments may include a semiconductor processing chamber 178 that includes one or more gas lines 170 for providing processing gasses into the semiconductor processing chamber 178 and exhaust lines 172 for removing byproducts from the semiconductor processing chamber 178. While not shown, it is to be appreciated that gas may also be injected into the semiconductor processing chamber 178 through a plasma showerhead assembly, e.g., assembly 370 for evenly distributing the processing gases over a substrate 174.

In one or more embodiments, the substrate 174 is supported on a chuck 176. For example, the chuck 176 may be any suitable chuck, such as an electrostatic chuck. The chuck 176 may also include cooling lines and/or a heater to provide temperature control to the substrate 174 during processing. Due to the modular configuration of the high-frequency emission modules described herein, embodiments allow for the processing tool 100 to accommodate any sized substrate 174. For example, the substrate 174 may be a semiconductor wafer (e.g., 200 mm, 300 mm, 450 mm, or larger). Alter-native embodiments also include substrates 174 other than semiconductor wafers. For example, embodiments may include a processing tool 100 configured for processing glass substrates, (e.g., for display technologies).

In one or more embodiments, the processing tool 100 includes a modular high-frequency emission source 104. The modular high-frequency emission source 104 includes an array of high-frequency emission modules 105. In one or more embodiments, each high-frequency emission module 105 independently includes an oscillator module 106, an amplification module 130, and an applicator 142. The oscillator module 106 may include a plurality of oscillator modules 106. The applicators 142 are schematically shown as being integrated into the dielectric faceplate 350. The skilled artisan will appreciate that the disclosure is not limited to the applicators 142 being integrated into the assembly 370.

In one or more embodiments, the oscillator module 106 and the amplification module 130 may comprise electrical components that are solid state electrical components. In one or more embodiments, each of the plurality of oscillator modules 106 are independently communicatively coupled to different amplification modules 130. In some embodiments there may be a 1:1 ratio between oscillator modules 106 and amplification modules 130. For example, each oscillator module 106 may be electrically coupled to a single amplification module 130.

In one or more embodiments, each oscillator module 106 independently generates high-frequency electromagnetic radiation that is transmitted to the amplification module 130. After processing by the amplification module 130, the electromagnetic radiation is transmitted to the applicator 142. In one or more embodiments, the applicators 142 each emit electromagnetic radiation into the semiconductor processing chamber 178.

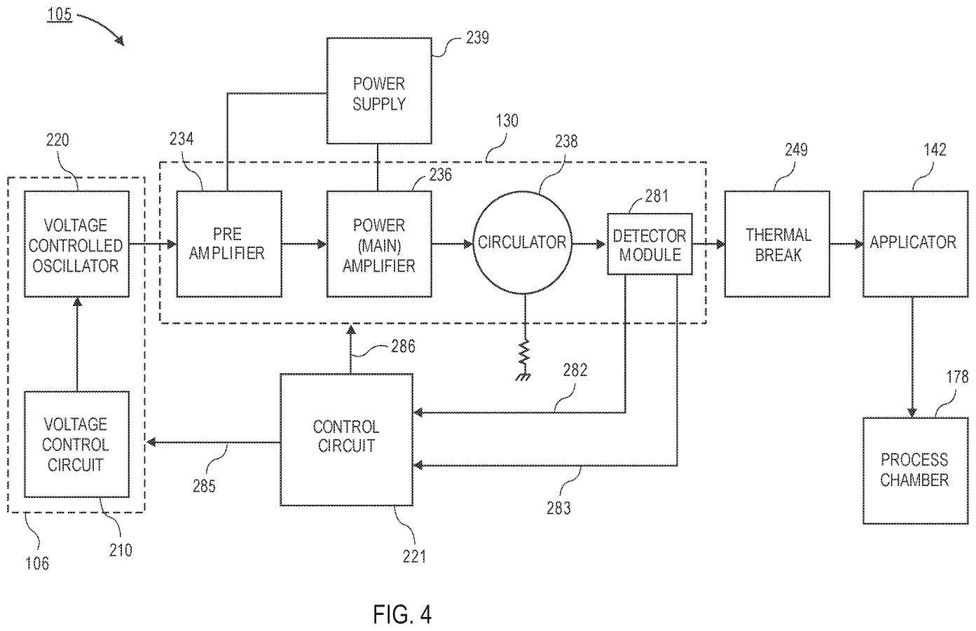

FIG. 4 illustrates a block diagram of a high-frequency emission module 105. In one or more embodiments, the high-frequency emission module 105 comprises the plurality of oscillator modules 106. Each oscillator module 106 may independently include a voltage control circuit 210 for providing an input voltage to a voltage controlled oscillator 220 in order to produce high-frequency electromagnetic radiation at a desired frequency. One or more embodiments include an input voltage in a range of from 1 V to 10V of DC. In one or more embodiments, the voltage controlled oscillator 220 is an electronic oscillator whose oscillation frequency is controlled by the input voltage. According to one or more embodiments, the input voltage from the voltage control circuit 210 results in the voltage controlled oscillator 220 oscillating at a desired frequency. In some embodiments, the high-frequency electromagnetic radiation has a frequency in a range of from about 0.1 MHz to about 30 MHz. In some embodiments, the high-frequency electromagnetic radiation has a frequency in a range of from about 30 MHz to about 300 MHz. In some embodiments, the high-frequency electro-magnetic radiation has a frequency in a range of from about 300 MHz to about 1 GHz. In some embodiments, the high-frequency electromagnetic radiation has a frequency in a range of from about 1 GHz to about 300 GHz.

According to one or more embodiments, the electromagnetic radiation is transmitted from the voltage controlled oscillator 220 to the amplification module 130. The amplification module 130 may include a driver/pre-amplifier 234 and a main power amplifier 236, and each of the driver/pre-amplifier 234 and the main power amplifier 236 are independently coupled to a power supply 239. According to one or more embodiments, the amplification module 130 may operate in a pulse mode. For example, the amplification module 130 may have a duty cycle in a range of from 1% to 99%. In specific embodiments, the amplification module 130 may have a duty cycle in a range of from 15% to 50%.

In some embodiments, the electromagnetic radiation may be transmitted to the thermal break 249 and the applicator 142 after being processed by the amplification module 130. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. The skilled artisan will appreciate that the detector module 281 may be located at one or more different locations in the system (e.g., between the circulator 238 and the thermal break 249). In some embodiments, the control circuit module 221 interprets the forward power 283 and the reflected power 282, and determines the level for the control signal 285 that is communicatively coupled to the oscillator module 106 and the level for the control signal 286 that is communicatively coupled to the amplification module 130. In some embodiments, control signal 285 adjusts the oscillator module 106 to optimize the high-frequency radiation coupled to the amplification module 130. In some embodiments, control signal 286 adjusts the amplification module 130 to optimize the output power coupled to the applicator 142 through the thermal break 249.

Accordingly, one or more embodiments allow for an increased percentage of the forward power to be coupled into the semiconductor processing chamber 178, and increases the available power. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator. Furthermore, the mechanical motion may not be as precise as the change in frequency that may be provided by a voltage controlled oscillator 220.

In some embodiments, a total delivered power from the microwave plasma source is equal to level of forward power 283 minus the level of reflected power 282. In some embodiments, the total delivered power from microwave plasma source is in a range of about 2300 Watts (W) to about 3800 Watts (W), such as, for example, 3325 Watts (W).

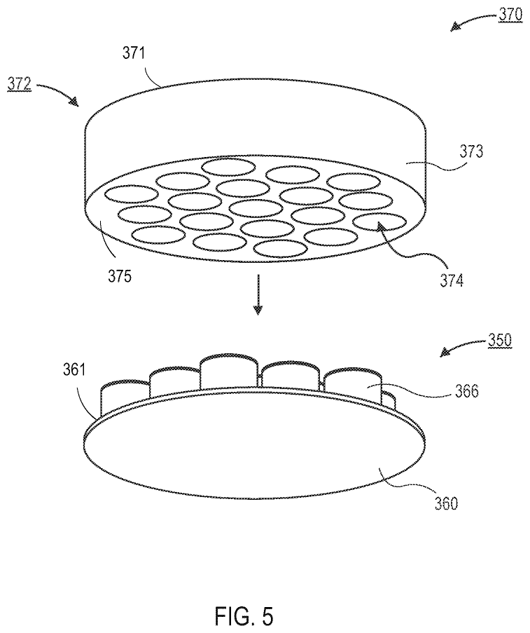

Referring now to FIG. 5, a schematic exploded perspective view of a plasma showerhead assembly 370 (hereinafter referred to as “assembly 370”) is shown.

The assembly 370 comprises a conductive plate 372 and a dielectric faceplate 350. As indicated by the arrow, the conductive plate 372 fits over and around the dielectric faceplate 350. In the illustrated embodiment of FIG. 5, the assembly 370 is shown as having a substantially circular shape. However, the skilled artisan will appreciate that the assembly 370 may have any suitable shape such as polygonal, elliptical, wedge shaped, or the like.

The conductive plate 372 comprises a conductive body 373 including a first surface 371 and a second surface 375 opposite to the first surface defining a conductive plate thickness, a plurality of resonator openings 374 extending from the first surface 371 through the conductive plate 372 to the second surface 375 of the conductive plate 372, gas channels within the conductive plate thickness, a plurality of conductive plate gas openings on the second surface 375 of the conductive plate 372 in fluid communication with the gas channels within the conductive plate thickness.

In some embodiments, the dielectric faceplate 350 comprises a first surface 361 and a second surface 360 opposite to the first surface 361 defining a dielectric faceplate thickness, a plurality of dielectric resonators 366 protruding from the first surface 361 and configured so that the resonators 366 fit into the plurality of the resonator openings 374 of the conductive plate 372 when assembled, each resonator 366 having a geometric center; and a plurality of dielectric faceplate gas openings extending through the dielectric faceplate thickness.

In some embodiments, monopole antennas 588 may extend into holes 365 in the dielectric resonators 366. The monopole antennas 588 are each electrically coupled to power sources (e.g., high-frequency emission modules 105).

The dielectric faceplate 350 may include any number of dielectric resonators 366. The plurality of dielectric resonators 366 can be arranged in any suitable arrangement. In some embodiments, the plurality of dielectric resonators 366 are arranged in a manner such that the dielectric resonators 366 uniformly distribute the microwave plasma in a semiconductor processing chamber. In some embodiments, the plurality of dielectric resonators 366 are arranged in a manner such that the dielectric resonators 366 uniformly distribute the microwave plasma in a processing chamber, such as, for example, a 300 mm chamber. In some embodiments, each dielectric resonator 366 is configured to provide up to 200 Watts (W) of power. In some embodiments, the total delivered power from microwave source is in a range of about 2300 Watts (W) to about 3800 Watts (W), such as, for example, 3325 Watts (W).

The conductive body 373 may include any suitable conductive material. For example, the conductive body 373 may be aluminum or the like. The plurality of resonator openings 374 may pass entirely through a thickness of the conductive body 373. The resonator openings 374 may be sized to receive the dielectric resonators 366. For example, as the conductive plate 372 is displaced towards the dielectric faceplate 350 (as indicated by the arrow in FIG. 5) the dielectric resonators 366 will be inserted into the plurality of resonator openings 374.

In the illustrated embodiment of FIG. 5, the conductive plate 372 is shown as a single conductive body 373. However, the skilled artisan will appreciate that the conductive plate 372 may comprise one or more discrete conductive components. The discrete components may be individually grounded, or the discrete components may be joined mechanically or by any form of metallic bonding, to form a single electrically conductive body 373.

In some embodiments, the dielectric faceplate 350 and the plurality of dielectric resonators 366 are a monolithic structure. That is, in embodiments where the dielectric faceplate 350 and the plurality of dielectric resonators 366 are a monolithic structure, there is no physical interface between a bottom of the dielectric resonators 366 and the dielectric faceplate 350. As used herein, a “physical interface” refers to a first surface of a first discrete body contacting a second surface of a second discrete body.

In other embodiments, the dielectric faceplate 350 and the dielectric resonators 366 are discrete components. Each of the dielectric resonators 366 are a portion of the applicator 142 used to inject high-frequency electromagnetic radiation into a processing chamber, such as the semiconductor processing chamber 178.

In some embodiments, the dielectric faceplate 350 comprises a dielectric material. For example, the dielectric faceplate 350 may be a ceramic material. In some embodiments, one suitable ceramic material that may be used for the dielectric faceplate 350, as an example, is aluminum oxide (Al₂O₃). In specific embodiments where the dielectric faceplate 350 and the plurality of dielectric resonators 366 are a monolithic structure, the monolithic structure may be fabricated from a single block of material. In other embodiments, a rough shape of the dielectric faceplate 350 may be formed with a molding process, and subsequently machined to provide the final structure with the desired dimensions. For example, green state machining and firing may be used to provide the desired shape of the dielectric faceplate 350. In the illustrated embodiment, the dielectric resonators 366 are shown as having a circular cross-section (when viewed along a plane parallel to the dielectric faceplate 350). However, the skilled artisan will appreciate that the dielectric resonators 366 may comprise many different cross-sections. For example, the cross-section of the dielectric resonators 366 may have any shape that is centrally symmetric.

In one or more unillustrated embodiments, the dielectric faceplate 350 includes one or more rings configured to separate the sidewall of the plurality of resonator openings 374 in the conductive plate 372 from the sidewall of the dielectric resonator 366. The rings may be electrically coupled to the conductive body 373 and are grounded during operation of the processing tool. Accordingly, the entire length of the sidewall is covered by a grounded surface. It has been advantageously found that covering the entire length of the sidewall with a grounded surface improves the resonance characteristics of the dielectric faceplate 350 and provides improved coupling of the high-frequency electromagnetic radiation into the processing chamber, such as semiconductor processing chamber 178.

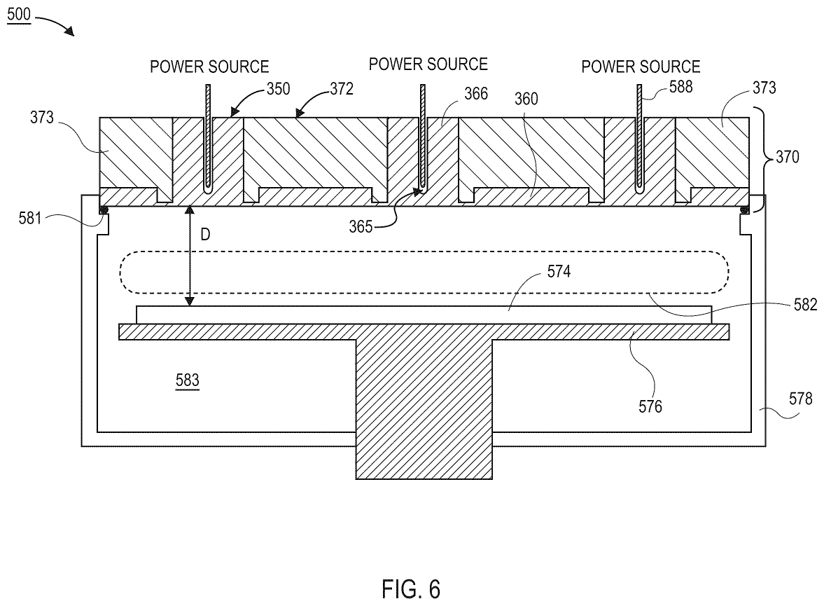

FIG. 6 illustrates a cross-sectional view of a processing tool 500 according to one or more embodiments. In one or more embodiments, the processing tool 500 comprises a semiconductor processing chamber 578 that is sealed by an assembly 370. For example, the assembly 370 may rest against one or more o-rings 581 to provide a vacuum seal to an interior volume 583 of the semiconductor processing chamber 578. In other embodiments, the assembly 370 may interface with the semiconductor processing chamber 578. That is, the assembly 370 may be part of a lid that seals the semiconductor processing chamber 578. In some embodiments, the processing tool 500 may comprise a plurality of processing volumes (which may be fluidically coupled together), with each processing volume independently having a plasma showerhead assembly, such as, for example the assembly 370. One or more of the operations of method 10 can be performed in the processing tool 500.

In some embodiments, a chuck 576 or the like may support a workpiece 574 (e.g., wafer, substrate, etc.). In one or more embodiments, the assembly 370 is spaced a distance D from the workpiece 574. The distance D may be any suitable distance. In some embodiments, the interior volume 583 may be suitable for striking a plasma 582. That is, the semiconductor processing chamber 578 may be a vacuum chamber.

In one or more embodiments, the semiconductor substrate 50 is the substrate 174 in the processing tool 100. In one or more embodiments, the semiconductor substrate 50 is the workpiece 574 in the processing tool 500. The method 10 and/or the method 20 described herein may be implemented in any of the processing tools described herein.

One or more embodiments of the disclosure are directed to a non-transitory computer readable medium including instructions, that, when executed by a controller of a processing chamber, cause the processing chamber to perform one or more of the operations of the method 10 and/or the method 20.

The disclosure will now be described with reference to the following examples.

### EXAMPLES

### Comparative Example 1

A silicon oxide (SiOx) film was deposited directly on a semiconductor substrate having a feature, e.g., a trench, having a top surface, two sidewalls comprising a dielectric material, and a bottom comprising a metallic material extending into the semiconductor substrate. In some experiments, the semiconductor substrate includes a high aspect ratio feature.

The silicon oxide (SiOx) film was deposited on the semiconductor substrate by a plasma-enhanced atomic layer deposition (PEALD) process. The PEALD process included exposing the semiconductor substrate to a silicon-containing precursor, purging the semiconductor substrate, exposing the semiconductor substrate to an oxygen-containing plasma, and purging. In some experiments, PEALD process included exposing the semiconductor substrate to a silicon-containing precursor, purging the semiconductor substrate, exposing the semiconductor substrate to an oxygen-containing plasma, purging, exposing the semiconductor substrate to a treatment plasma, and purging.

In each experiment, the oxygen-containing plasma and the treatment plasma were generated by a capacitively coupled plasma (CCP) source.

The silicon oxide (SiOx) film quality was measured under dilute hydrofluoric (HF), acid etch solution (dilute HF 100:1) and a wet etch rate (WER) of the silicon oxide (SiOx) film was measured in nm/min. The measured WER of the silicon oxide (SiOx) film outside the trench (e.g., on the top surface) is in a range of from 10 nm/min to 12 nm/min. The measured WER of the silicon oxide (SiOx) film inside the trench (e.g., on the top surface) is in a range of from 10 nm/min to 12 nm/min.

### Inventive Example 1

A silicon oxide (SiOx) film was deposited directly on a semiconductor substrate having a feature, e.g., a trench, having a top surface, two sidewalls comprising a dielectric material, and a bottom comprising a metallic material extending into the semiconductor substrate. In some experiments, the semiconductor substrate included a high aspect ratio feature.

The silicon oxide (SiOx) film was deposited on the semiconductor substrate by a plasma-enhanced atomic layer deposition (PEALD) process. The PEALD process included exposing the semiconductor substrate to a silicon-containing precursor, purging the semiconductor substrate, exposing the semiconductor substrate to an oxygen-containing plasma, and purging. In some experiments, PEALD process included exposing the semiconductor substrate to a silicon-containing precursor, purging the semiconductor substrate, exposing the semiconductor substrate to an oxygen-containing plasma, purging, exposing the semiconductor substrate to a treatment plasma, and purging.

In each experiment, the oxygen-containing plasma and the treatment plasma were generated by a microwave plasma source. In some experiments, the oxygen-containing plasma and the treatment plasma were generated by the modular microwave plasma source described herein.

The silicon oxide (SiOx) film quality was measured under dilute hydrofluoric (HF), acid etch solution (dilute HF 100:1) and a wet etch rate (WER) of the silicon oxide (SiOx) film was measured in nm/min. Inventive Example 1, which corresponds to the methods described herein (e.g., the method 10 and/or the method 20) advantageously provides a silicon oxide (SiOx) film that has a reduced etch amount in Angstroms (Å) using dilute HF 100:1, which represents an improved wet etch rate (WER), relative to Comparative Example 1.

Advantageously, the measured WER of the silicon oxide (SiOx) film provided by Inventive Example 1 has about the same wet etch rate (WER) in different regions of the semiconductor substrate feature, e.g., the trench, having the top surface, two sidewalls, and the bottom. Advantageously, the measured WER of the silicon oxide (SiOx) film of Inventive Example 1 outside the trench (e.g., on the top surface) is less than 6 nm/min. Advantageously, the measured WER of the silicon oxide (SiOx) film of Inventive Example 1 inside the trench (e.g., on the top surface) is less than 6 nm/min.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method comprising:
exposing a semiconductor substrate to a silicon-containing precursor and an oxygen-containing plasma to deposit a silicon oxide (SiOx) film, wherein the oxygen-containing plasma is a microwave plasma generated by a microwave plasma source.

2. The method of claim 1, performed at a temperature in a range of from 100° C. to 700° C.

3. The method of claim 1, comprising a plasma-enhanced atomic layer deposition (PEALD) process.

4. The method of claim 1, wherein the oxygen-containing plasma comprises one or more of oxygen (O₂), ozone (O₃), or nitrous oxide (N₂O).

5. The method of claim 1, comprising exposing the semiconductor substrate to the silicon-containing precursor for a time period in a range of from 0.1 seconds to 60 seconds.

6. The method of claim 1, comprising exposing the semiconductor substrate to the oxygen-containing plasma for a time period in a range of from 0.1 seconds to 120 seconds.

7. The method of claim 1, further comprising exposing the semiconductor substrate to a treatment plasma.

8. The method of claim 7, wherein the treatment plasma is a microwave plasma generated by a microwave plasma source.

9. The method of claim 7, wherein the treatment plasma comprises oxygen (O₂) and one or more of nitrogen (N₂), argon (Ar), or helium (He).

10. The method of claim 9, wherein the treatment plasma consists essentially of oxygen (O₂) and nitrogen (N₂).

11. The method of claim 9, wherein the treatment plasma consists essentially of oxygen (O₂) and argon (Ar).

12. The method of claim 9, wherein the treatment plasma consists essentially of oxygen (O₂) and helium (He).

13. The method of claim 7, comprising exposing the semiconductor substrate to the treatment plasma for a time period in a range of from 0.1 seconds to 120 seconds.

14. The method of claim 1, wherein the semiconductor substrate comprises at least one feature, the at least one feature defining a trench having a top surface, a bottom surface, and two sidewalls.

15. A method of manufacturing a semiconductor device, the method comprising:
exposing a semiconductor substrate to a silicon-containing precursor and an oxygen-containing plasma to deposit a silicon oxide (SiOx) film wherein the oxygen-containing plasma comprises one or more of oxygen (O₂), ozone (O₃), or nitrous oxide (N₂O), the oxygen-containing plasma is a microwave plasma generated by a microwave plasma source, and the method is performed at a temperature in a range of from 100° C. to 700° C.

16. The method of claim 15, comprising exposing the semiconductor substrate to the silicon-containing precursor for a time period in a range of from 0.1 seconds to 60 seconds and exposing the semiconductor substrate to the oxygen-containing plasma for a time period in a range of from 0.1 seconds to 120 seconds.

17. The method of claim 15, further comprising exposing the semiconductor substrate to a treatment plasma, the treatment plasma comprising a microwave plasma including oxygen (O₂) and one or more of nitrogen (N₂), argon (Ar), or helium (He).

18. The method of claim 17, comprising exposing the semiconductor substrate to the treatment plasma for a time period in a range of from 0.1 seconds to 120 seconds.

19. The method of claim 15, wherein the semiconductor device includes a 3D-NAND structure.

20. The method of claim 15, wherein the semiconductor device includes a dynamic random-access memory (DRAM) structure.
